(19) United States
(12) Patent Application Publication
(10) Pub. No.: US 2024/0186955 A1
(43) Pub. Date: Jun. 6, 2024

(54) DIGITAL ENVELOPE TRACKING SUPPLY MODULATOR

(71) Applicant: MEDIATEK INC., Hsin-Chu (TW)

(72) Inventors: Chen-Yen Ho, Hsinchu City (TW); Hsiang-Hui Chang, Hsinchu City (TW); Ya-Ting Hsu, Hsinchu (TW); Ke-Horng Chen, Hsinchu (TW)

(73) Assignee: MEDIATEK INC., Hsin-Chu (TW)

(21) Appl. No.: 18/525,884

(22) Filed: Dec. 1, 2023

Related U.S. Application Data
(60) Provisional application No. 63/385,788, filed on Dec. 2, 2022.

(51) Int. Cl. H03F 1/02

(52) U.S. Cl. CPC H03F 1/0216; H03F 3/21

(57) ABSTRACT

A digital envelope tracking (DET) supply modulator is provided. The DET supply modulator includes a switching converter, a dynamic switched-capacitor circuit and a digital control circuit. The switching converter converts an input supply voltage into an output envelope tracking (ET) voltage according to a first control signal. The dynamic switched-capacitor circuit outputs multiple supplement voltages for supplementing alternating current (AC) components of the output ET voltage by multiple stages. More particularly, the dynamic switched-capacitor circuit comprises multiple switched-capacitor cells and a selection circuit, wherein the selection circuit is coupled to the multiple switched-capacitor cells. In detail, the multiple switched-capacitor cells generate the multiple supplement voltages, respectively, and the selection circuit controls switching of each of the multiple switched-capacitor cells according to a second control signal. The digital control circuit generates the first control signal and the second control signal according to a target envelope waveform of the output ET voltage.

### CROSS REFERENCE TO RELATED APPLICATIONS

This application claims the benefit of U.S. Provisional Application No. 63/385, 788, filed on Dec. 2, 2022. The content of the application is incorporated herein by reference.

### BACKGROUND

The present invention is related to envelope tracking of power amplifiers, and more particularly, to a digital envelope tracking supply modulator.

In order to optimize power efficiency of a power amplifier (PA) in a radio frequency (RF) system, envelope tracking of a supply voltage of the PA is widely developed. By dynamically modulating the supply voltage of the PA, the PA can operate under an optimized level of the supply voltage, thereby obtaining an optimized performance. In some related art, analog envelope tracking techniques are proposed, where linear amplifiers (LAs) are typically needed and can be power consuming. In addition, high bandwidth applications are widely developed, which makes the analog envelope tracking techniques face some bottlenecks such as signal delay and printed circuit board (PCB) trace limitations.

Some related arts propose some digital envelope tracking techniques to remove the usage of LAs. The digital envelope tracking techniques still have some disadvantages, however. For example, a voltage divider which provides a fixed number of voltage levels can be adopted for digital envelope tracking, where the fixed number of voltage levels is hard to make all conditions achieve the best power efficiency due to power loss caused by charging or discharging. Thus, there is a need for a novel architecture, in order to improve an overall power efficiency of envelope tracking.

### SUMMARY

An objective of the present invention is to provide a digital envelope tracking (DET) supply modulator, which can solve the problem of the related art.

At least one embodiment of the present invention provides a DET supply modulator. The DET supply modulator comprises a switching converter, a dynamic switched-capacitor circuit and a digital control circuit, wherein the digital control circuit is coupled to the switching converter and the dynamic switched-capacitor circuit. The switching converter is configured to convert an input supply voltage into an output envelope tracking (ET) voltage according to a first control signal. The dynamic switched-capacitor circuit is configured to output multiple supplement voltages for supplementing alternating current (AC) components of the output ET voltage by multiple stages. More particularly, the dynamic switched-capacitor circuit comprises multiple switched-capacitor cells and a selection circuit, wherein the selection circuit is coupled to the multiple switched-capacitor cells. In detail, the multiple switched-capacitor cells is configured to generate the multiple supplement voltages in the multiple stages, respectively, and the selection circuit is configured to control switching of each of the multiple switched-capacitor cells according to a second control signal. In addition, the digital control circuit is configured to generate the first control signal and the second control signal according to a target envelope waveform of the output ET voltage.

The DET supply modulator provided by the embodiment of the present invention utilize the switching converter to act as a quasi-DC converter to decide a quasi-DC level of the output ET voltage and utilize the dynamic switched-capacitor circuit to act as a fast supplementary AC source. In addition, some design parameters (e.g. the number of DET levels, a DET switching frequency) can be determine according to pre-calculated power-added efficiency (PAE) of the PA and converter loss of the DET supply modulator, in order to optimize an overall power efficiency.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a digital envelope tracking supply modulator according to an embodiment of the present invention.

FIG. 2 is a diagram illustrating an example of a hysteresis control circuit according to an embodiment of the present invention.

FIG. 3 is a diagram illustrating a first example of a switched-capacitor sub-cell according to an embodiment of the present invention.

FIG. 4 is a diagram illustrating a second example of a switched-capacitor sub-cell according to an embodiment of the present invention.

FIG. 5 is a diagram illustrating a third example of a switched-capacitor sub-cell according to an embodiment of the present invention.

FIG. 6 is a diagram illustrating optimization of a digital envelope tracking switching frequency and a digital envelope tracking level number according to an embodiment of the present invention.

FIG. 7 is a diagram illustrating details of a digital control circuit of the digital envelope tracking supply modulator shown in FIG. 1 according to an embodiment of the present invention.

FIG. 8 is a diagram illustrating a first scheme of an error reduction circuit of the digital envelope tracking supply modulator shown in FIG. 1 according to an embodiment of the present invention.

FIG. 9 is a diagram illustrating a second scheme of an error reduction circuit of the digital envelope tracking supply modulator shown in FIG. 1 according to an embodiment of the present invention.

FIG. 10 is a diagram illustrating a double supply tracking technique according to an embodiment of the present invention.

FIG. 11 is a diagram illustrating a state machine of the digital envelope tracking supply modulator shown in FIG. 1 according to an embodiment of the present invention.

### DETAILED DESCRIPTION

Certain terms are used throughout the following description and claims, which refer to particular components. As one skilled in the art will appreciate, electronic equipment manufacturers may refer to a component by different names. This document does not intend to distinguish between components that differ in name but not in function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

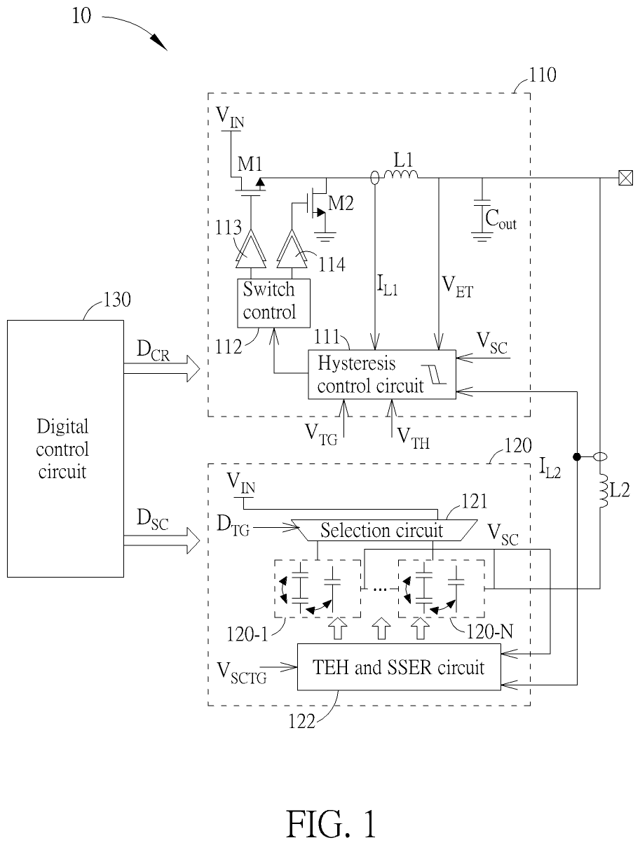

FIG. 1 is a diagram illustrating a digital envelope tracking (DET) supply modulator 10 according to an embodiment of the present invention. As shown in FIG. 1, the DET supply modulator 10 may comprise a switching converter 110 (e.g. a buck converter), a dynamic switched-capacitor circuit 120 and a digital control circuit 130, where the digital control circuit 130 is coupled to the switching converter 110 and the dynamic switched-capacitor circuit 120. In this embodiment, the switching converter 110 is configured to convert an input supply voltage V_{IN} into an output envelope tracking (ET) voltage V_{ET} on an output capacitor C_{OUT} according to a first control signal such as a control circuit D_{CR}. The dynamic switched-capacitor circuit 120 is configured to output multiple supplement voltages V_{SC} for supplementing alternating current (AC) components of the output ET voltage by multiple stages (e.g. outputting a corresponding supplement voltage V_{SC} in each of the multiple stages). More particularly, the dynamic switched-capacitor circuit 120 may comprises multiple switched-capacitor cells such as 120-1, . . . and 120-N, and a selection circuit 121, where the selection circuit 121 is coupled to the switched-capacitor cells 120-1, . . . and 120-N. In this embodiment, the switched-capacitor cells 120-1, . . . and 120-N are configured to generate the supplement voltages V_{SC} in the multiple stages, respectively (e.g. each of the switched-capacitor cells 120-1, . . . and 120-N is configured to generate a corresponding supplement voltage V_{SC}), and the selection circuit 121 is configured to control switching of each of the switched-capacitor cells 120-1, . . . and 120-N according to a second control signal such as a control signal D_{SC}. More particularly, the selection circuit 121 may control the switching of each of the switched-capacitor cells 120-1, . . . and 120-N according to a control signal D_{TG} (which may correspond to a target value of each of the supplement voltages V_{SC}, and may be a portion of the control signal D_{SC} or a derivative signal generated according to the control signal D_{SC}). In addition, the digital control circuit 130 is configured to generate the control signals D_{CR} and D_{SC} according to a target envelope waveform of the output ET voltage V_{ET}.

As shown in FIG. 1, the switching converter 110 may comprise at least one power transistor such as M1 and M2, a driving control logic such as a switch control circuit 112 (labeled “Switch control” in FIG. 1 for brevity), and a hysteresis control circuit 111, where the switch control circuit 112 is coupled to the power transistor M1 and M2 via drivers 113 and 114, respectively, and the hysteresis control circuit 111 is coupled to the switch control circuit 112. The power transistor M1 and M2 are configured to pull up or pull low the output ET voltage V_{ET} via an output inductor L1 according to driving control signals from the drivers113 and 114. The switch control circuit 112 is configured to generate the driving control signals for being transmitted by the drivers113 and 114. The hysteresis control circuit 111 is configured to control a frequency and a duty cycle of the driving control signals according to the control signal D_{CR} (more particularly, a target value V_{TG} of the output ET voltage V_{ET}, which may be a portion of the control signal D_{CR} or a derivative signal generated according to the control signal D_{CR}), a threshold value V_{TH} (which may be a predetermined offset parameter), the output ET voltage V_{ET}, the multiple supplement voltages V_{SC} and current sensing information (e.g. current information I_{L1} of the inductor L1 and/or current information I_{L2} of an inductor L2 coupled between the switching converter 110 and the dynamic switched-capacitor circuit 120). Thus, by referring to output voltages and loading information (e.g. the current sensing information) of both the switching converter 110 and the dynamic switched-capacitor 120, the hysteresis control circuit 111 may control a hysteresis window of the switching converter 110 to thereby determine frequencies and duty cycles of a high-side duration (which corresponds to an increased amount of a charging current flowing to the inductor L1) and a low-side duration (which corresponds to an reduced amount of a charging current flowing to the inductor L1), in order to avoid the conflict of the switching converter 110 and the dynamic switched-capacitor 120.

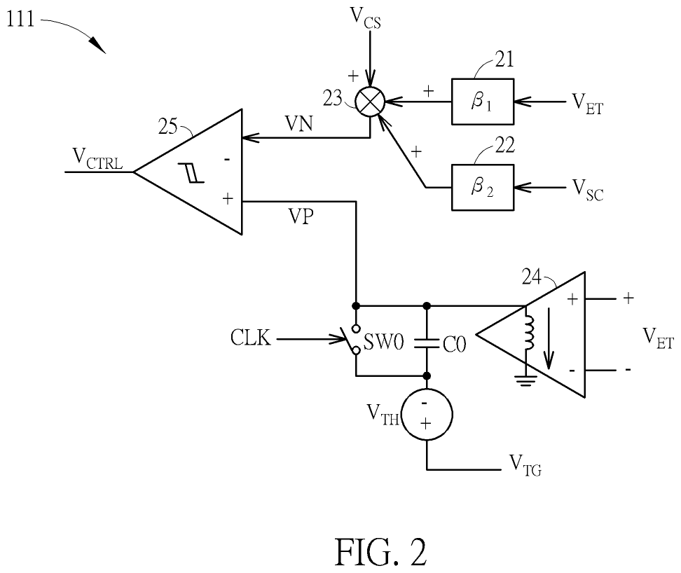

FIG. 2 is a diagram illustrating an example of the hysteresis control circuit 111 according to an embodiment of the present invention. As shown in FIG. 2, by configuration of operators 21, 22 and 23, a first value VN may be calculated according to current sensing information V_{CS} (which may include the current information I_{L1} and I_{L2}), the output ET voltage V_{ET} and each of the supplement voltages V_{SC} (e.g. VN=I_{L1}+β₁×V_{ET}+β₂×V_{SC}), a second value VP may be obtained according to the output ET voltage V_{ET}, the target value V_{TG} and the threshold value V_{TH} with control of a switch SW0 (which is controlled by a clock CLK) and a capacitor C0 (e.g. charging the capacitor C0 by the output ET voltage V_{ET} based on an initial level defined by the threshold value V_{TH}), where a hysteresis comparator 25 may generate a control signal V_{CTRL} (which is transmitted to the switch control circuit 112) according to the first value VN and the second value VP, but the present invention is not limited thereto. According to the hysteresis control circuit 111 shown in FIG. 2, when a target value of the target waveform (e.g. the target value V_{TG}) is increased (which means an output target of the output ET voltage V_{ET} increases), the threshold value V_{TH} is reduced (which means a trigger condition of a DC-to-DC conversion of the switching converter 110 is lowered, and more output energy from the switching converter 110 is required), the output ET voltage V_{ET} is reduced (which means output energy is insufficient), a supplement voltage (e.g. the corresponding supplement voltage V_{SC} in each of the multiple stages) of the multiple supplement voltages V_{SC} is reduced (which means output energy is insufficient), or the current sensing information V_{CS} is reduced (which means output energy is insufficient), the first value VN may be reduced and the second value VP may be increased, where the hysteresis control circuit may thereby adjust the duty cycle of the at least one driving control signal, for example, making the duty cycles controlled by the control signal V_{CTRL} (e.g. the high-side duration mentioned above) be increased, in order to increase energy supplemented from the switching converter 110 to the output ET voltage.

In the embodiment of FIG. 1, the dynamic switched-capacitor circuit 120 may further comprise an error reduction circuit such as a transient enhancement (TEH) and steady-state error reduction (SSER) circuit 122, where the TEH and SSER circuit 122 is configured to provide a push current or a pull current to any switched-capacitor cell (e.g. a switched-capacitor cell 120-X, where X is an integer within an interval from 1 to N) of the switched-capacitor cells 120-1 to 120-N in response to a steady-state error (e.g. a difference between the supplement voltage V_{SC} and a target value V_{SCTG} of the supplement voltage V_{SC}) of the supplement voltage V_{SC} generated by the switched-capacitor cell 120-X. Other details of the TEH and SSER circuit 122 will be described later.

In some embodiment, any of the switched-capacitor cells 120-1 to 120-N may be implemented by a switched-capacitor sub-cell. In some embodiment, any of the switched-capacitor cells 120-1 to 120-N may be implemented by a combination of multiple identical switched-capacitor sub-cells. In some embodiment, any of the switched-capacitor cells 120-1 to 120-N may be implemented by a combination of multiple different switched-capacitor sub-cells.

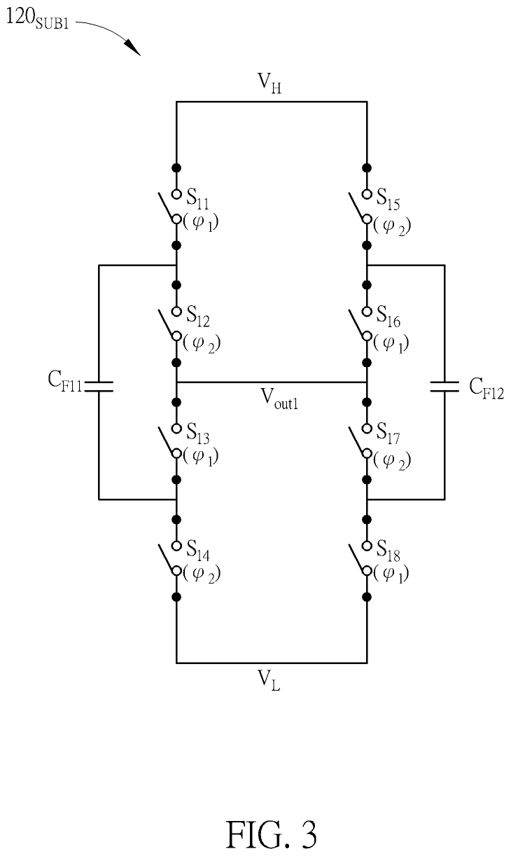

FIG. 3 is a diagram illustrating a first example of a switched-capacitor sub-cell such as a switched-capacitor sub-cell 120_{SUB1} (which may be included in any of the switched-capacitor cells 120-1, . . . and 120-N) according to an embodiment of the present invention. In the embodiment of FIG. 3, the switched-capacitor sub-cell 120_{SUB1} is coupled between a first reference voltage providing a high reference level V_{H} and a second reference voltage providing a low reference level V_{L}, where the switched-capacitor sub-cell 120_{SUB1} may comprise flying capacitors C_{F11} and C_{F12}, where the connection of the flying capacitors C_{F11} and C_{F12} may be controlled by switches S₁₁, S₁₂, S₁₃, S₁₄, S₁₅, S₁₆, S₁₇ and S₁₈, the switches S₁₁, S₁₃, S₁₆ and S₁₈ may be turned on in a first phase φ₁, and the switches S₁₂, S₁₄, S₁₅ and S₁₇ may be turned on in a second phase φ₂. With the control shown in FIG. 3, an output voltage Vₒᵤₜ₁ provided by the switched-capacitor sub-cell 120_{SUB1} may be equal to ((½)×(V_{H}−V_{L})).

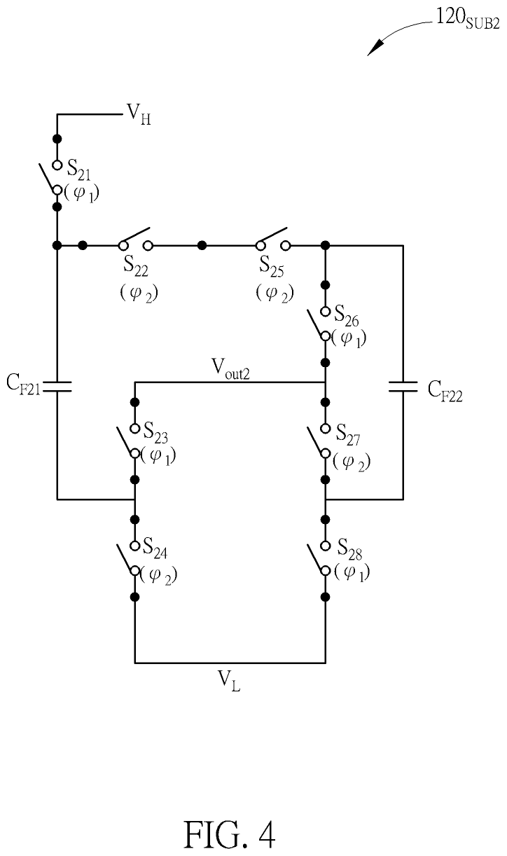

FIG. 4 is a diagram illustrating a second example of a switched-capacitor sub-cell such as a switched-capacitor sub-cell 120_{SUB2} (which may be included in any of the switched-capacitor cells 120-1, . . . and 120-N) according to an embodiment of the present invention. In the embodiment of FIG. 4, the switched-capacitor sub-cell 120_{SUB2} is coupled between the first reference voltage providing the high reference level V_{H} and the second reference voltage providing the low reference level V_{L}, where the switched-capacitor sub-cell 120_{SUB2} may comprise flying capacitors C_{F21} and C_{F22}, where the connection of the flying capacitors C_{F21} and C_{F22} may be controlled by switches S₂₁, S₂₂, S₂₃, S₂₄, S₂₅, S₂₆, S₂₇ and S₂₈, the switches S₂₁, S₂₃, S₂₆ and S₂₈ may be turned on in the first phase φ₁, and the switches S₂₂, S₂₄, S₂₅ and S₂₇ may be turned on in the second phase φ₂. With the control shown in FIG. 4, an output voltage Vₒᵤₜ₂ provided by the switched-capacitor sub-cell 120_{SUB2} may be equal to ((⅓)×(V_{H}−V_{L})).

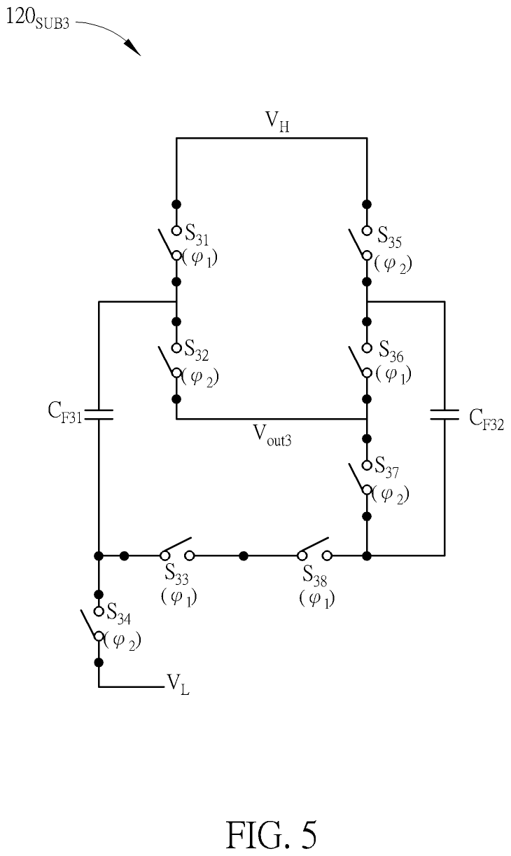

FIG. 5 is a diagram illustrating a third example of a switched-capacitor sub-cell such as a switched-capacitor sub-cell 120_{SUB3} (which may be included in any of the switched-capacitor cells 120-1, . . . and 120-N) according to an embodiment of the present invention. In the embodiment of FIG. 5, the switched-capacitor sub-cell 120_{SUB3} is coupled between the first reference voltage providing the high reference level V_{H} and the second reference voltage providing the low reference level V_{L}, where the switched-capacitor sub-cell 120_{SUB3} may comprise flying capacitors C_{F31} and C_{F32}, where the connection of the flying capacitors C_{F31} and C_{F32} may be controlled by switches S₃₁, S₃₂, S₃₃, S₃₄, S₃₅, S₃₆, S₃₇ and S₃₈, the switches S₃₁, S₃₃, S₃₆ and S₃₈ may be turned on in the first phase φ₁, and the switches S₃₂, S₃₄, S₃₅ and S₃₇ may be turned on in the second phase φ₂. With the control shown in FIG. 5, an output voltage Vₒᵤₜ₃ provided by the switched-capacitor sub-cell 120_{SUB2} may be equal to ((⅔)×(V_{H}−V_{L})).

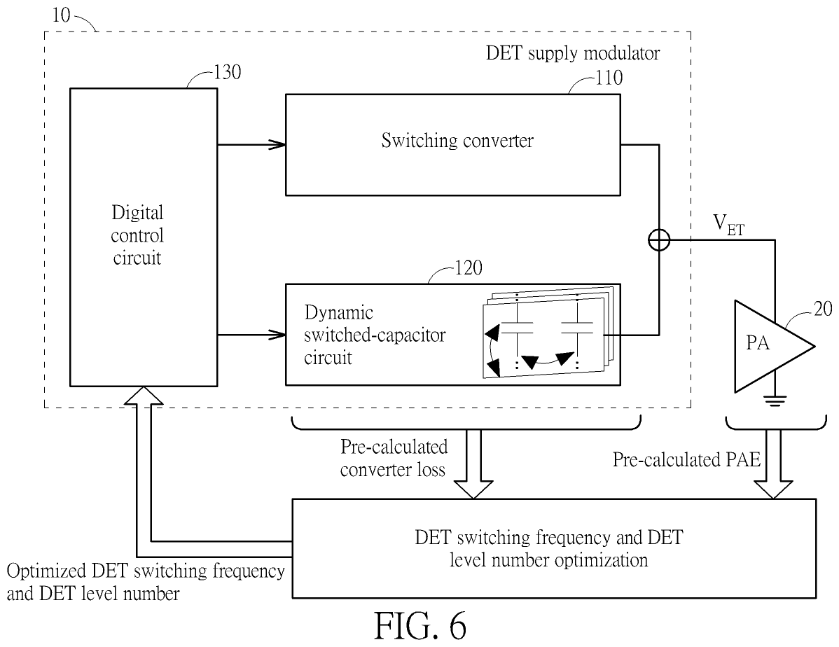

FIG. 6 is a diagram illustrating optimization of a DET switching frequency and a DET level number according to an embodiment of the present invention. As shown in FIG. 6, the output ET voltage V_{ET} is transmitted to a power amplifier (PA) 20 as a supply voltage, where the target envelope waveform of the output ET voltage V_{ET} has multiple candidate levels, the DET level number represent the number of the multiple candidate levels, and the target envelope waveform is updated based on the DET switching frequency. It should be noted that although a greater value of the DET level number and a greater value of the DET switching frequency can reach a higher precision of optimized supply tracking of the PA 20, the greater value of the DET level number and the greater value of the DET switching frequency make the DET supply modulator less power efficient. Thus, the DET level number and the DET switching frequency may be dynamically determined according to an overall power efficiency of the DET supply modulator and the PA, to make the number of the multiple candidate levels and the DET switching frequency varies in response to a calculated result of the overall power efficiency. In detail, the digital control circuit 130 may generate pre-calculated converter loss of the DET supply modulator 10 (more particularly, the switching converter 110 and the dynamic switched-capacitor circuit 120 within the DET supply modulator 10) and pre-calculated power-added efficiency (PAE) of the PA 20 under different supplies and different frequencies. By summarizing results of the pre-calculated converter loss of the DET supply modulator 10 and the PAE of the PA 20, optimized values of the DET switching frequency and the DET level number may be obtained. Thus, the DET supply modulator 10 may have a dynamic number of the multiple candidate levels (e.g. a dynamic DET level number), which enables a fine level of digital voltage level selection that saves power and charges/discharges output (e.g. the output ET voltage VET) with just-enough energy.

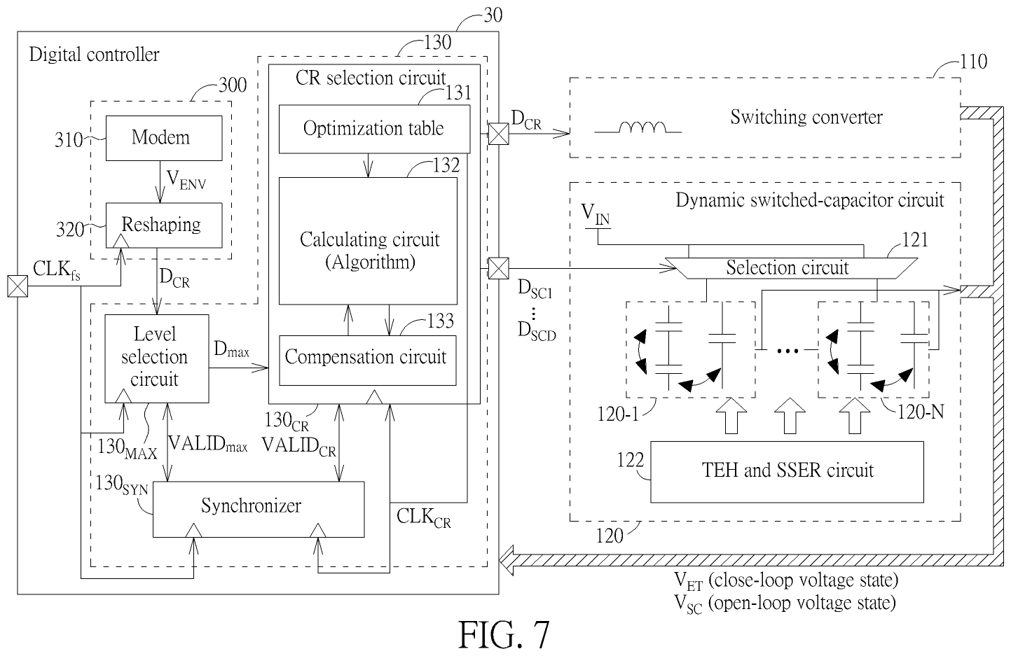

FIG. 7 is a diagram illustrating details of the digital control circuit 130 of the DET supply modulator 10 shown in FIG. 1 according to an embodiment of the present invention, where the digital control circuit 130 may be included in a digital controller 30 of a radio frequency (RF) system. In addition to the digital control circuit 130, the digital controller 30 may further comprise a digital processing circuit 300, where the digital processing circuit 300 may comprise a modulator-demodulator (Modem) 310 and a reshaping circuit 320 (labeled “Reshaping” in FIG. 7 for brevity). The Modem 310 may generate a continuous target envelope waveform V_{ENV}, and the reshaping circuit 320 may convert the continuous target envelope waveform V_{ENV} into an initial target envelope waveform D_{ENV} (e.g. by performing an analog-to-digital conversion with a sampling clock CLK_{fs}).

In this embodiment, the digital control circuit may comprise a level selection circuit 130_{MAX}. After the optimization mentioned above, the DET level number is determined, which means the multiple candidate levels of the target envelope waveform of the output ET voltage V_{ET} are determined. Thus, the level selection circuit 130_{MAX} is configured to select corresponding levels among the multiple candidate levels to generate the target envelope waveform such as Dₘₐₓ for representing the initial target envelope waveform D_{ENV}, where each of the corresponding levels is not less than any level of the initial target envelope waveform within a corresponding period. For example, the level selection circuit 130_{MAX} may utilize the multiple candidate levels to form the target envelope waveform Dₘₐₓ, in order to make the target envelope waveform Dₘₐₓ as much fit the initial target envelope waveform D_{ENV} as possible under a condition where the target envelope waveform Dₘₐₓ is always above the initial target envelope waveform D_{ENV}, which ensure that the target envelope waveform Dₘₐₓ is sufficient to allow the PA 20 to properly operates.

After the optimization mentioned above, the DET switching frequency such as f_{CR} of a conversion ratio (CR) clock CLK_{CR} is determined, where the DET switching frequency f_{CR} of the CR clock CLK_{CR} may be different from a sampling clock f_{S} of the sampling clock CLK_{fs}. The digital control circuit 130 may further comprise a synchronizer 130_{SYN}, which is configured to control the level selection circuit 130_{MAX} to select the corresponding levels among the multiple candidate levels based on the DET switching frequency f_{CR}, to make the target envelope waveform Dₘₐₓ be updated based on the DET switching frequency f_{CR}. For example, the synchronizer 130_{SYN} may generate a valid signal VALIDₘₐₓ for the level selection circuit 130_{MAX}, in order to make the level selection circuit 130_{MAX} output the corresponding levels with the DET switching frequency f_{CR} (e.g. controlling a data rate of the target envelope waveform Dₘₐₓ to be equal to the DET switching frequency f_{CR}).

In this embodiment, the digital control circuit 130 may further comprise a CR selection circuit 130_{CR}, which is configured to generate the control signals D_{CR} and D_{SC} (more particularly, generating control signals D_{SC1}, . . . and D_{SCN} by N stages for respectively controlling the switching of the switched-capacitor cells 120-1 to 120-N) based on the DET switching frequency f_{CR} (e.g. with control of a valid signal VALID_{CR} generated by the synchronizer 130_{SYN}). As shown in FIG. 7, the CR selection circuit may comprise an optimization table 131, a calculating circuit 132 and a compensation circuit 133. The optimization table 131 may execute the optimization mentioned in the embodiment of FIG. 6 and thereby record optimization results such as the DET switching frequency f_{CR} and the DET level numbers (more particularly, the multiple candidate levels obtained according to the DET level numbers). The calculating circuit 132 is coupled to the optimization table 131, and is configured to execute an algorithm to generate the control signals D_{CR} and D_{SC} (e.g. the control signals D_{SC1}, . . . and D_{SCN} for the N stages) in digital formats according to the target envelop waveform Dₘₐₓ (e.g. according to the corresponding levels). For example, the calculating circuit 132 may execute a binary-ratio-reconfigurable selection algorithm to derive target values of the supplement voltages V_{SC} stage by stage (e.g. with calculation of a (+2)-bits input signal Vi and a (N+1)-bits output signal Vo), to thereby generate corresponding digital control signals (e.g. the control signals D_{SC1}, . . . and D_{SCN}) stage by stage, where the calculation of the input signal Vi and the output signal Vo may be performed as follows:

$$\frac{{V}_{o}}{{V}_{i}} = \frac{\{ {A}_{N} , … , {A}_{0} \}}{\{ 1 , {B}_{N} , … , {B}_{0} \}} = \frac{{\sum }_{i = 0}^{N} \frac{{A}_{i}}{{2}^{( N - i + 1 )}}}{1 + {\sum }_{i = 0}^{N} \frac{{B}_{i}}{{2}^{( N - i + 1 )}}}$$

{A_{N}, . . . , A₀} may represent respective bits of a digital control signal applied to the dynamic switched-capacitor circuit 120 that result in the output signal Vo, and {1, B_{N}, . . . , B₀} may represent respective bits of the digital control signal applied to the dynamic switched-capacitor circuit 120 that result in the input signal Vi. By the binary-ratio-reconfigurable selection algorithm, the calculating circuit 132 may provide a side voltage range with digitally controlled bits for stage-to-stage switching control of the dynamic switched-capacitor circuit 120. The compensation circuit 133 is coupled to the calculating circuit 132, and is configured to correct the control signal D_{CR} and the control signal D_{SC} (e.g. the control signals D_{SC1}, . . . and D_{SCN}) according to a close-loop voltage state (e.g. the output ET voltage V_{ET}) and an open-loop voltage state (e.g. the supplement voltages V_{SC}) of the DET supply modulator 10 stage by stage. For example, when the compensation circuit 133 detects that any of the close-loop voltage state and the open-loop voltage state fails to meet target state(s) thereof, the compensation circuit 133 may thereby adjust the control signal D_{CR} and the control signal D_{SC} (e.g. the control signals D_{SC1}, . . . and D_{SCN}) to compensate errors of the close-loop voltage state and/or the open-loop voltage state.

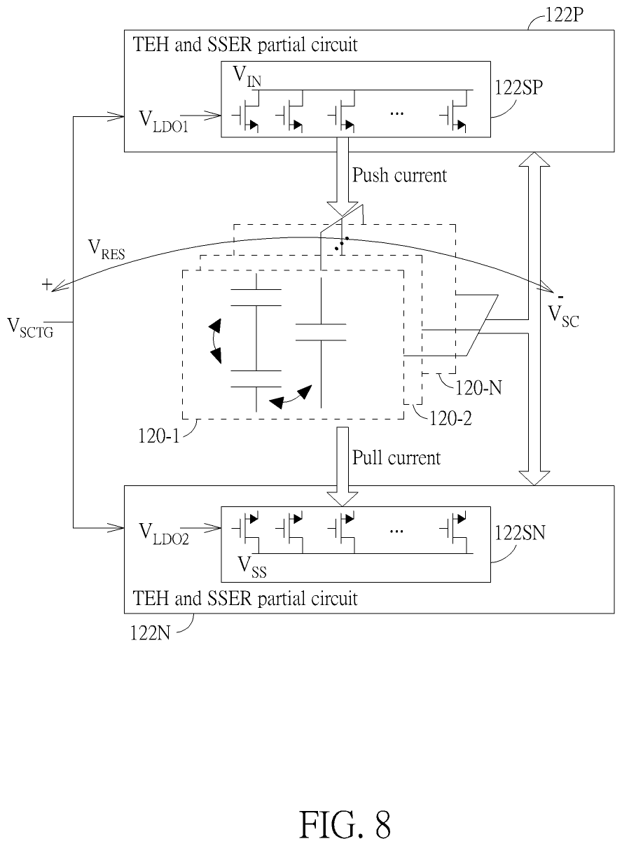

FIG. 8 is a diagram illustrating a first scheme of the TEH and SSER circuit 122 of the DET supply modulator 10 shown in FIG. 1 according to an embodiment of the present invention. In this embodiment, the TEH and SSER circuit 122 may comprise TEH and SSER partial circuits 122P and 122N, where the TEH and SSER partial circuit 122P is configured to provide a push current in response to a positive steady-state error (e.g. V_{RES}>0 when the supplement voltage V_{SC} is less than the target value), and the TEH and SSER partial circuit 122N is configured to provide a pull current in response to a negative steady-state error (e.g. V_{RES}<0 when the supplement voltage V_{SC} is greater than the target value). In this embodiment, the TEH and SSER partial circuit 122P may comprise at least one power switch such as 122SP coupled between the input supply voltage V_{IN} and the switched-capacitor cell 120-X (e.g. the one selected by the selection circuit 121 from the switched-capacitor cells 120-1 to 120-N), where the power switch 122SP may comprise at least one transistor (e.g. one or more transistor), and a gate terminal of the at least one transistor may be controlled by a gate control signal V_{LDO1} which is generated according to the steady-state error V_{RES}. In particular, the TEH and SSER partial circuit 122P may control a magnitude of the push current in a manner similar to a low-dropout regulator (LDO) loop such as a hybrid LDO loop. For example, the power switch 122SP can be turned on in response to the steady-state error V_{RES}, to provide the push current for reducing the steady-state error V_{RES}. In addition, the TEH and SSER partial circuit 122N may comprise at least one power switch such as 122SN coupled between the switched-capacitor cell 120-X (e.g. the one selected by the selection circuit 121 from the switched-capacitor cells 120-1 to 120-N) and a reference voltage VSS (e.g. a ground voltage), where the power switch 122SN may comprise at least one transistor (e.g. one or more transistors), and a gate terminal of the at least one transistor may be controlled by a gate control signal V_{LDO2} which is generated according to the steady-state error V_{RES}. In particular, the TEH and SSER partial circuit 122N may control a magnitude of the pull current in a manner similar to the LDO loop. For example, the power switch 122SN can be turned on in response to the steady-state error V_{RES}, to provide the pull current for reducing the steady-state error V_{RES}.

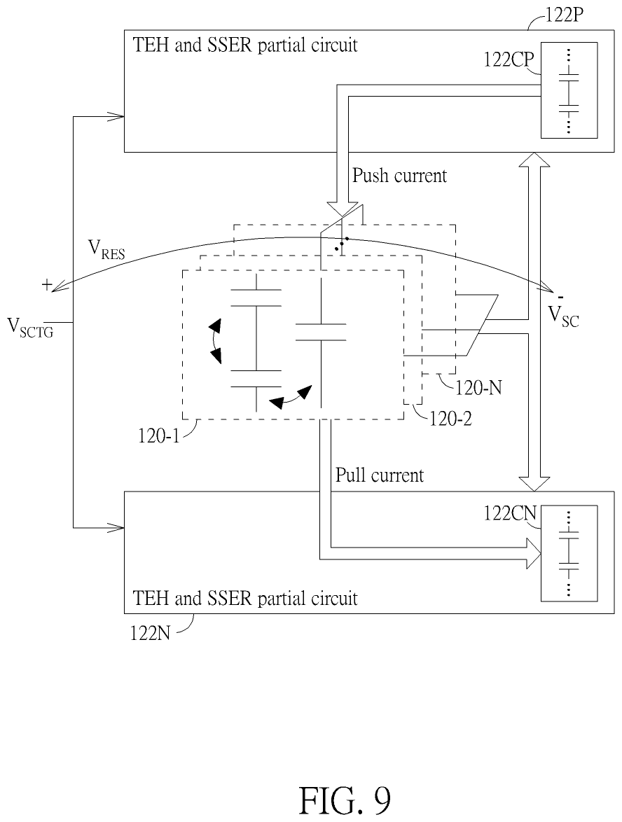

FIG. 9 is a diagram illustrating a second scheme of the TEH and SSER circuit 122 (more particularly, the TEH and SSER partial circuits 122P and 122N therein) of the DET supply modulator 10 shown in FIG. 1 according to an embodiment of the present invention. In this embodiment, the TEH and SSER partial circuit 122P may comprise at least one charge storage element such as 122CP, which is configured to provide the push current by transferring charges to the switched-capacitor cell 120-X (e.g. the one selected by the selection circuit 121 from the switched-capacitor cells 120-1 to 120-N) for reducing the steady-state error V_{RES}. In addition, the TEH and SSER partial circuit 122N may comprise at least one charge storage element such as 122CN, which is configured to provide the pull current by receiving the charges from the switched-capacitor cell 120-X for reducing the steady-state error V_{RES}. As shown in FIG. 9, each of the charge storage elements 122CP and 122CN may comprise capacitors connected in series. It should be noted that when the charge storage element 122CN receives the charges from the switched-capacitor cell 120-X, the charges can be stored in the storage element 122CN for being transferred to another switched-capacitor cell in response to a steady-state error of a supplement voltage generated by the other switched-capacitor cell. That is, the charge storage element 122CN, which provide the pull current, can be configured to provide the push current in a next stage, thereby achieving energy recycling and improving power efficiency.

The TEH and SSER circuit 122 (more particularly, the TEH and SSER partial circuits 122P and 122N therein) shown in FIG. 8 and/or FIG. 9 can effectively solve the tradeoff problem between driving capability (e.g. the steady-state error reduction) and step up/down speed (e.g. transient enhancement). In some embodiment, the techniques shown in the FIG. 8 and FIG. 9 can be both applied to the TEH and SSER circuit 122, where the TEH and SSER circuit 122 can provide a sudden push or pull current to stage-to-stage outputs (e.g. the supplement voltage V_{SC}) and overall output during transient, to thereby supplement inefficiency output energy in steady-state.

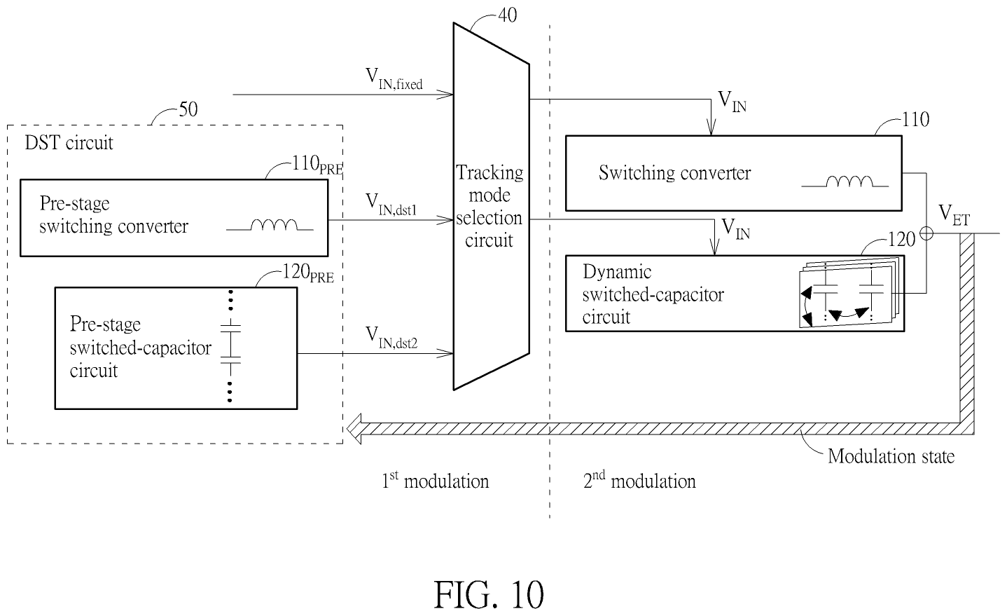

FIG. 10 is a diagram illustrating a double supply tracking (DST) technique according to an embodiment of the present invention. In some embodiment, the DET supply modulator 10 may comprise a DST circuit 50 configured to provide a modulated supply voltage to be the input supply voltage V_{IN}. In one embodiment, the DST circuit 50 may comprise a pre-stage switching converter 110_{PRE}, which is configured to convert a fixed supply voltage V_{IN,fixed} into a modulated supply voltage V_{IN,dst1} to be the input supply voltage V_{IN} according to a pre-stage target envelope waveform of the input supply voltage V_{IN}, thereby making the input supply voltage V_{IN} be variable. In one embodiment, the DST circuit 50 may comprise a pre-stage switched-capacitor circuit 120_{PRE}, which is configured to generate a modulated supply voltage V_{IN,dst2} according to a pre-stage target envelope waveform of the input supply voltage V_{IN}, thereby making the input supply voltage V_{IN} be variable. In this embodiment, the DET supply modulator 10 may utilize a tracking mode selection circuit 40 to select one of the fixed supply voltage V_{IN,fixed}, the modulated supply voltage V_{IN,dst1} from the pre-stage switching converter 110_{PRE}, and the modulated supply voltage V_{IN,dst2} from the pre-stage switched-capacitor circuit 120_{PRE} to be the input supply voltage V_{IN}, but the present invention is not limited thereto. It should be noted that the pre-stage target envelope waveform of any of the pre-stage switching converter 110_{PRE} and the pre-stage switched-capacitor circuit 120_{PRE} may be provided by the digital control circuit 130 (not shown in FIG. 10 for brevity), where modulation state information (e.g. the output ET voltage V_{ET} and/or the supplement voltages V_{SC}) may be feedback for compensating the pre-stage target envelope waveform, but the present invention is not limited thereto. Detailed implementations of the pre-stage switching converter 110_{PRE} and the pre-stage switched-capacitor circuit 120_{PRE} may be deduced by analogy (e.g. by referring to that of the switching converter 110 and the dynamic switched-capacitor circuit 120), and will not be described in detail here for brevity. In some embodiment, the DST circuit 50 may comprise other types of supply modulation circuits such as cascaded element, but the present invention is not limited thereto. As the input supply voltage V_{IN} is variable (e.g. scalable), a better tracking performance (e.g. tracking speed, efficiency) can be achieved. More particularly, under different tracking mode, the input supply voltage V_{IN} may have different levels, allowing the supply tracking to be effectively optimized.

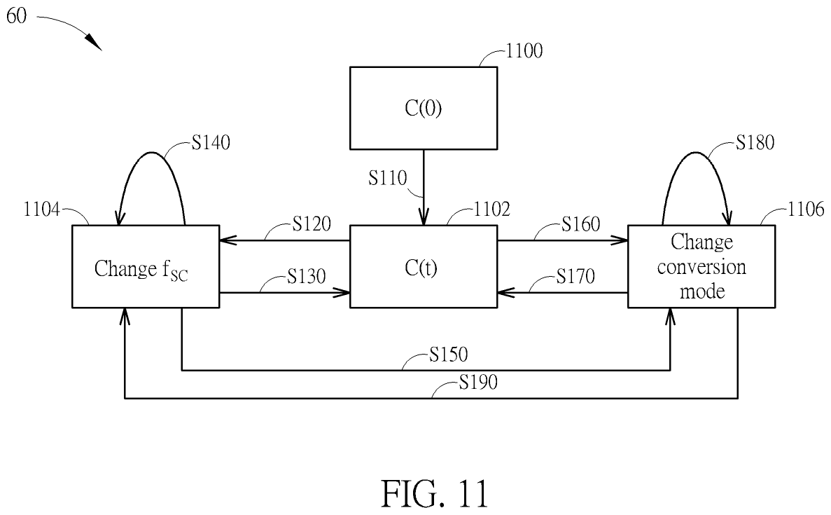

FIG. 11 is a diagram illustrating a state machine 60 of the DET supply modulator 10 shown in FIG. 1 according to an embodiment of the present invention, where the state machine 60 may be implemented in the digital control circuit 130, but the present invention is not limited thereto. In this embodiment, the state machine 60 may control a configuration setting flow according to loading information (e.g. stage-to-stage state of the dynamic switched-capacitor circuit 120), and more particularly, the state machine 60 is configured to control an operating frequency f_{SC} and a conversion mode (e.g. a switching method for a specific conversion ratio) of the switching of the switched-capacitor cells 120-1 to 120-N according to a detected supplement voltage (e.g. the supplement voltage V_{SC} which is detected in a certain stage) of the supplement voltages V_{SC} and a target value of the detected supplement voltage (e.g. the target value V_{SCTG} of the supplement voltage V_{SC}).

In State 1100, an initial selection of capacitor sizes may be set, where an initial capacitor state C(0) may be described by a matrix as follows:

$$C ( 0 ) = ( \begin{matrix}{C}_{fly 11} ( 0 ) & ⋯ & {C}_{fly 1 M} ( 0 ) & ⋯ & {C}_{1 O} ( 0 ) \\ ⋮ & & ⋮ & & ⋮ \\ {C}_{flyN 1} ( 0 ) & ⋯ & {C}_{flyNM} ( 0 ) & ⋯ & {C}_{NO} ( 0 )\end{matrix} )$$

C_{fly11}(0) to C_{fly1M}(0) may represent equivalent capacitors of the dynamic switched-capacitor circuit 120 in a first stage, and C₁₀(0) may represent an initial value of the equivalent capacitors of the dynamic switched-capacitor circuit 120 of the first stage. Deduced by analogy, C_{flyN1}(0) to C_{flyNM}(0) may represent equivalent capacitors of the dynamic switched-capacitor circuit 120 in a N^{th} stage, and C_{NO}(0) may represent an initial value of the equivalent capacitors of the dynamic switched-capacitor circuit 120 of the N^{th} stage. When the state machine receives a CR command (e.g. conversion of a certain DET level begins) as illustrated by Step S110, the state machine 60 may enter State 1102.

In State 1102, the initial capacitor state C(0) may be calculated and updated (e.g. updating the equivalent capacitors and corresponding target values of the supplement voltage V_{SC}) according to the selected CR mode and the operating frequency f_{SC}, as illustrated by a present capacitor state C(t). When the detected supplement voltage does not reach the target value and a difference between the detected supplement voltage and the target value is greater than a predetermined threshold (e.g. the detected supplement voltage is far from the target value), the state machine 60 may enter State 1104 as illustrated by Step S120 to change the operating frequency f_{SC}. When the detected supplement voltage does not reach the target value and the difference between the detected supplement voltage and the target value is less than the predetermined threshold (e.g. the detected supplement voltage is close to the target value), the state machine may enter State 1106 as illustrated by Step S160 to change the conversion mode (e.g. changing the conversion ratio of the dynamic switched-capacitor circuit 120 for fine tune).

In State 1104, after the operating frequency f_{SC} is changed, when the detected supplement voltage still fails to reach the target value and the difference between the detected supplement voltage and the target value is still greater than the predetermined threshold (e.g. the detected supplement voltage is still far from the target value), the state machine 60 may stay at State 1104 as illustrated by Step S140 to change the operating frequency f_{SC} again. When the detected supplement voltage still fails to reach the target value but the difference between the detected supplement voltage and the target value becomes less than the predetermined threshold (e.g. the detected supplement voltage becomes close enough for fine tune), the state machine 60 may enter State 1106 as illustrated by Step S150 to change the conversion mode (e.g. changing the conversion ratio of the dynamic switched-capacitor circuit 120 for fine tune). When the detected supplement voltage reaches the target value, the state machine 60 may enter State 1102 as illustrated by Step S130.

In State 1106, after the conversion mode is changed, when the detected supplement voltage fails to reach the target value but a counting time does not reach a predetermined period yet, the state machine 60 may stay at State 1106 as illustrated by Step S180 to change the conversion mode again. When the detected supplement voltage fails to reach the target value within the predetermined period (e.g. the counting time reaches the predetermined period), the state machine 60 may enter State 1104 as illustrated by Step S190 to change the operating frequency f_{SC}. When the detected supplement voltage reaches the target value, the state machine 60 may enter State 1102 as illustrated by Step S170.

It should be noted that if the conversion mode is changed, the equivalent capacitors and the corresponding target values of the supplement voltage V_{SC} may change, which means the capacitor state C(t) may be updated from C(t1) to C(t2), and therefore the target values of the supplement voltages V_{SC} of respective stages may be updated.

To summarize, the DET supply modulator 10 provided by the embodiments of the present invention utilizes the switching converter 110 to provide quasi-DC energy and utilize the dynamic switched-capacitor circuit 120 to act as a fast supplementary AC source. More particularly, with the control proposed by the present invention, the dynamic switched-capacitor circuit 120 can be charged with just-enough energy, making the supply tracking more energy efficient. In comparison with analog ET (AET) and DET of related arts (referred to as typical AET and typical DET for brevity), as for PA tracking precision, the typical AET is still the best, the dynamic DET (i.e. operations of the DET supply modulator 10) of the present invention is the second best, and the typical DET is the worst. As for power efficiency of the supply modulator, the dynamic DET of the present invention is the best, the typical DET is the second best, and the typical AET is the worst. With overall consideration of the PA tracking precision and the supply modulator efficiency, the dynamic DET can achieve the best overall performance.

Those skilled in the art will readily observe that numerous modifications and alterations of the device and method may be made while retaining the teachings of the invention. Accordingly, the above disclosure should be construed as limited only by the metes and bounds of the appended claims

What is claimed is:

1. A digital envelope tracking (DET) supply modulator, comprising:
a switching converter, configured to convert an input supply voltage into an output envelope tracking (ET) voltage according to a first control signal;
a dynamic switched-capacitor circuit, configured to output multiple supplement voltages for supplementing alternating current (AC) components of the output ET voltage by multiple stages, wherein the dynamic switched-capacitor circuit comprises:
multiple switched-capacitor cells, configured to generate the multiple supplement voltages in the multiple stages, respectively;
a selection circuit, coupled to the multiple switched-capacitor cells, configured to control switching of each of the multiple switched-capacitor cells according to a second control signal;
a digital control circuit, coupled to the switching converter and the dynamic switched-capacitor circuit, configured to generate the first control signal and the second control signal according to a target envelope waveform of the output ET voltage.

2. The DET supply modulator of claim 1, wherein the switching converter comprises:
at least one power transistor, configured to pull up or pull low the output ET voltage according to at least one driving control signal;
a driving control logic, coupled to the at least one power transistor, configured to generate the at least one driving control signal; and
a hysteresis control circuit, coupled to the driving control logic, configured to control a frequency and a duty cycle of the at least one driving control signal according to the first control signal, a threshold value, the output ET voltage, the multiple supplement voltages and current sensing information.

3. The DET supply modulator of claim 2, wherein when a target value of the target waveform is increased, the threshold value is reduced, the output ET voltage is reduced, a supplement voltage of the multiple supplement voltages is reduced, or the current sensing information is reduced, the hysteresis control circuit adjusts the duty cycle of the at least one driving control signal, in order to increase energy supplemented from the switching converter to the output ET voltage.

4. The DET supply modulator of claim 1, wherein the target envelope waveform has multiple candidate levels, the target envelope waveform is updated based on a DET switching frequency, the output ET voltage is transmitted to a power amplifier (PA) as a supply voltage, and a number of the multiple candidate levels and the DET switching frequency are dynamically determined according to an overall power efficiency of the DET supply modulator and the PA, to make the number of the multiple candidate levels and the DET switching frequency varies in response to a calculated result of the overall power efficiency.

5. The DET supply modulator of claim 4, wherein the digital control circuit comprises:
a level selection circuit, configured to select corresponding levels among the multiple candidate levels to generate the target envelope waveform for representing an initial target envelope waveform, wherein each of the corresponding levels is not less than any level of the initial target envelope waveform within a corresponding period.

6. The DET supply modulator of claim 5, wherein the digital control circuit further comprises:
a synchronizer, configured to control the level selection circuit to select the corresponding levels among the multiple candidate levels based on the DET switching frequency, to make the target envelope waveform be updated based on the DET switching frequency.

7. The DET supply modulator of claim 4, wherein the digital control circuit comprises:
a conversion ratio (CR) selection circuit, configured to generate the first control signal and the second control signal based on the DET switching frequency.

8. The DET supply modulator of claim 7, wherein the CR selection circuit comprises:
a calculating circuit, configured to execute an algorithm to generate the first control signal and the second control in digital formats according to the target envelop waveform.

9. The DET supply modulator of claim 8, wherein the CR selection circuit comprises:
a compensation circuit, coupled to the calculating circuit, configured to correct the first control signal and the second control according to the output ET voltage and the multiple supplement voltages.

10. The DET supply modulator of claim 1, wherein the dynamic switched-capacitor circuit further comprises:
an error reduction circuit, configured to provide a push current or a pull current to any switched-capacitor cell of the multiple switched-capacitor cells in response to a steady-state error of a supplement voltage generated by the switched-capacitor cell.

11. The DET supply modulator of claim 10, wherein the error reduction circuit comprises:
at least one power switch, coupled between the input supply voltage and the switched-capacitor cell, wherein the at least one power switch comprises at least one transistor, a gate terminal of the at least one transistor is controlled by a gate control signal which is generated according to the steady-state error;
wherein the at least one power switch is turned on in response to the steady-state error, to provide the push current or the pull current for reducing the steady-state error.

12. The DET supply modulator of claim 10, wherein the error reduction circuit comprises:
at least one charge storage element, configured to transfer charges to the switched-capacitor cell or receive the charges from the switched-capacitor cell for reducing the steady-state error.

13. The DET supply modulator of claim 12, wherein when the at least one charge storage element receives the charges from the switched-capacitor cell, the charges are stored in the at least one charge storage element for being transferred to another switched-capacitor cell in response to a steady-state error of a supplement voltage generated by the other switched-capacitor cell.

14. The DET supply modulator of claim 12, wherein the at least one charge storage element comprises capacitors connected in series.

15. The DET supply modulator of claim 1, further comprising:
a pre-stage switching converter, configured to convert a fixed supply voltage into the input supply voltage according to a pre-stage target envelope waveform of the input supply voltage, wherein the input supply voltage is variable.

16. The DET supply modulator of claim 1, further comprising:
a pre-stage switched-capacitor circuit, configured to generate the input supply voltage according to a pre-stage target envelope waveform of the input supply voltage, wherein the input supply voltage is variable.

17. The DET supply modulator of claim 1, further comprising:
a state machine, configured to control an operating frequency and a conversion mode of the switching of the multiple switched-capacitor cells according to a detected supplement voltage of the multiple supplement voltages and a target value of the detected supplement voltage.

18. The DET supply modulator of claim 17, wherein when the detected supplement voltage does not reach the target value and a difference between the detected supplement voltage and the target value is greater than a predetermined threshold, the state machine changes the operating frequency.

19. The DET supply modulator of claim 18, wherein after the operating frequency is changed, when the detected supplement voltage still fails to reach the target value but the difference between the detected supplement voltage and the target value becomes less than the predetermined threshold, the state machine changes the conversion mode.

20. The DET supply modulator of claim 17, wherein when the detected supplement voltage does not reach the target value and a difference between the detected supplement voltage and the target value is less than a predetermined threshold, the state machine changes the conversion mode.

21. The DET supply modulator of claim 20, wherein after the conversion mode is changed, when the detected supplement voltage fails to reach the target value within a predetermined period, the state machine changes the operating frequency.

22. The DET supply modulator of claim 1, wherein any of the multiple switched-capacitor cells comprises:
a switched-capacitor sub-cell, coupled between a first reference voltage and a second reference voltage, configured to provide an output voltage equal to any of ((½)×(V_{H}−V_{L})), ((⅓)×(V_{H}−V_{L})) and ((⅔)×(V_{H}−V_{L}));
wherein V_{H} represents a first reference level provided by the first reference voltage, and V_{L} represents a second reference level provided by the second reference voltage.
